(19) United States
(12) Patent Application Publication
(10) Pub. No.: US 2012/0134128 A1
(43) Pub. Date: May 31, 2012

(54) PORTABLE ELECTRONIC APPARATUS

(75) Inventors: Kenjiro OKAMOTO, Osaka (JP); Nobuyuki KITAMURA, Osaka (JP)

(73) Assignee: KYOCERA CORPORATION, Kyoto (JP)

(21) Appl. No.: 13/302,739

(22) Filed: Nov. 22, 2011

(30) Foreign Application Priority Data
Nov. 26, 2010 (JP) 2010-263620

(51) Int. Cl. H05K 7/02

(52) U.S. Cl. 361/807

(57) ABSTRACT

A portable electronic apparatus includes a first casing having a first display surface, a second casing having a second display surface, and a coupling mechanism that couples the first casing and the second casing to each other.

### CROSS-REFERENCE TO RELATED APPLICATIONS

This application claims priority from Japanese Patent Application No. 2010/263620 filed on Nov. 26, 2010, which is hereby incorporated by reference.

### BACKGROUND OF THE INVENTION

1. Field of the Invention

The present invention relates to portable electronic apparatuses constituted by a pair of casings coupled to each other.

2. Background Art

Conventionally, there have been known portable electronic apparatuses constituted by a pair of casings coupled to each other, in which both the casings are provided with respective display surfaces, thereby enabling both the display surfaces to offer a large amount of information to users.

In such portable electronic apparatuses, for example, a pair of casings are coupled to each other at respective side portions by means of a link member, and are moved relatively with each other by a rotating operation of the link member between a single-surface exposed state (a closed state) in which the pair of casings are overlaid on each other, the display surface (a first display surface) in the lower casing (a first casing) is covered with the upper casing (a second casing), and only the display surface (a second display surface) in the second casing is exposed, and a double-surface exposed state (an opened state) in which the second casing is moved with respect to the first casing, and the display surfaces of both the casings are exposed onto the same plane.

With the portable electronic apparatus, in the opened state, the first display surface and the second display surface are aligned on the same plane with each other. By setting the two display surfaces as a single large screen, it is possible to display an image through the large screen.

In the portable electronic apparatus, the first display surface and the second display surface are formed by a screen of a liquid crystal display, for example, and a second display forming the second display surface is attached to a front surface side (the display surface side) of one of a pair of cabinets constituting the second casing by using a hook structure including an engaging piece and an engaged piece, for example.

In the hook structure for the second casing, for example, the engaging piece is protruded integrally with the cabinet made of a resin and constituting the second casing, and the engaged piece is protruded integrally with a frame member made of a resin and holding the second display. For this reason, both the engaging piece and the engaged piece are made of the resins. In order to ensure a necessary strength for an engagement state, an engagement depth of the engaging piece and the engaged piece, more specifically, a plate thickness of the engaged piece is set to have a sufficient size, for example, 0.8 mm or more.

In the portable electronic apparatus, however, when the first casing and the second casing are brought into abutment to each other in the opened state, the sidewall of the casing extended along the edge of each of the first and second displays and the hook structure are provided between the displays. As a result, there is a problem in that a great gap is generated between the first display surface and the second display surface, resulting in a great breakage of a single image between the two display surfaces when the image is to be displayed with the two display surfaces set to be a single large screen.

Accordingly, it is an object of the present invention to provide a portable electronic apparatus having a first casing and a second casing coupled to each other through a coupling mechanism, in which an excellent image display can be carried out with two display surfaces set to be a single screen in an opened state in which the display surfaces of both of the casings are aligned on the same plane with each other.

### SUMMARY OF THE INVENTION

A portable electronic apparatus according to the present invention includes a first casing constituted by bonding a front-surface cabinet and a rear-surface cabinet to each other and including a display held on a holder member made of a sheet metal and having a display surface which can be visually recognized from a front surface side, a second casing coupled to the first casing, constituted by bonding a front-surface cabinet and a rear-surface cabinet to each other, and including a display held on a holder member made of a sheet metal and having a display surface which can be visually recognized from a front surface side, a coupling mechanism taking at least two states of a closed state in which the display surface of the display of the first casing is covered with a rear surface of the second casing and the display surface of the display of the second casing is exposed, and an opened state in which the second casing is moved from the closed state to expose the display surfaces of both of the displays onto the same plane, an engaging piece protruded integrally with the front-surface cabinet constituting at least one of the casings, and the holder member which holds the display provided in the casing, is provided with an engaged piece to be engaged with the engaging piece in a protruding manner integrally, and is to be engaged with the front-surface cabinet through a mutual engagement of the engaging piece and the engaged piece.

### BRIEF DESCRIPTION OF THE DRAWINGS

FIG. 1 is a perspective view illustrating a portable electronic apparatus according to an embodiment of the present invention, in a closed state;

FIG. 2 is a perspective view illustrating the portable electronic apparatus in the closed state with being reversed;

FIG. 3 is a perspective view illustrating the portable electronic apparatus, in a tilt state;

FIG. 4 is a perspective view illustrating the portable electronic apparatus, in the tilt state, when viewed at its rear side;

FIG. 5 is a perspective view illustrating the portable electronic apparatus in a first open state;

FIG. 6 is a perspective view illustrating the portable electronic apparatus in the first open state with being reversed;

FIG. 7 is a perspective view illustrating the portable electronic apparatus in a second open state;

FIG. 8 is a perspective view illustrating the portable electronic apparatus in the second open state with being reversed;

FIG. 9 is an exploded perspective view illustrating the portable electronic apparatus;

FIG. 10 is an exploded perspective view illustrating the portable electronic apparatus with being reversed;

FIG. 11 is a perspective view illustrating the portable electronic apparatus, wherein a portion thereof is further exploded from the state of FIG. 10;

FIG. 12 is a perspective view illustrating the portable electronic apparatus, wherein a portion thereof is further exploded from the state of FIG. 11;

FIG. 13 is a cross-sectional view illustrating the portable electronic apparatus;

FIG. 14 is a perspective view illustrating the portable electronic apparatus, wherein a portion thereof is further exploded from the state of FIG. 8;

FIGS. 15A and B are another cross-sectional views illustrating a transition of the portable electronic apparatus from a first open state A to a second open state B;

FIGS. 16A and B are cross-sectional views illustrating portions C and D in FIG. 15 in an enlarging manner;

FIGS. 17A to C are cross-sectional views illustrating a state of deformations of a flexible lead in a process for a transition from a closed state A to a second open state C through a first open state B;

FIG. 18 is a perspective view illustrating a pair of convex portions formed in the second casing in the closed state;

FIG. 19 is a perspective view illustrating a portion E in FIG. 18 in an enlarging manner;

FIG. 20 is a plan view illustrating the pair of convex portions formed in the second casing in the closed state;

FIG. 21 is a plan view illustrating a portion F in FIG. 20 in an enlarging manner;

FIG. 22 is an enlarged cross-sectional view illustrating main portions of the second casing at the position where a convex portion is formed;

FIG. 23 is an enlarged cross-sectional view illustrating a hook structure provided along the faced portions of a first casing and the second casing in an opened state;

FIG. 24 is a perspective view illustrating a state in which a second display and a front-surface cabinet are disassembled from a holder member of the second display;

FIG. 25 is an exploded perspective view illustrating the holder member and a frame member in the second display.

FIGS. 26A to D are a series of side views illustrating the first half of a process from the closed state to the second open state through the tilt state in the portable electronic apparatus according to the present invention;

FIGS. 27A to D are a series of side views illustrating the second half of the same process; and

FIGS. 28A and B are side views illustrating the portable electronic apparatus according to the present invention which is placed on a desk in a tilt state A and the second open state B.

### DETAILED DESCRIPTION OF EMBODIMENTS

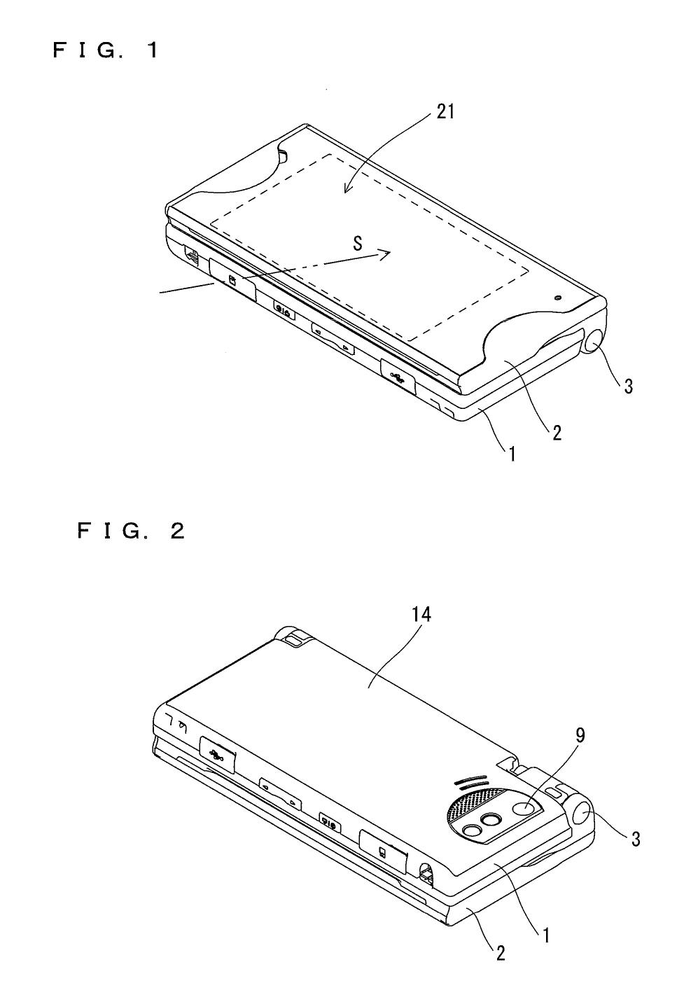

A portable electronic apparatus according to an embodiment of the present invention includes a first casing 1 having a first display surface 11 in its surface, a second casing 2 having a second display surface 21 in its surface, and a coupling mechanism 3 which couples the first casing 1 and the second casing 2 to each other, as illustrated in FIGS. 1 to 8.

Further, the first display surface 11 and the second display surface 21 are capable of displaying, thereon, characters or videos, as well as images.

As illustrated in FIG. 2, a photographing lens 9 is provided in the rear surface of the first casing 1.

In the case in which each portion of the components of the portable electronic apparatus is specified in the following description, “front (the side closer to the person viewing the figures)”, “rear”, “left” and “right” regarding the portable electronic apparatus illustrated in FIG. 1 as seen along a user's line of sight indicated by an arrow S in the figure will be also referred to as “front”, “rear”, “left” and “right” regardless of the attitude of the portable electronic apparatus in the other drawings.

As illustrated in FIG. 13, inside the first casing 1, there are placed a first touch panel 13 and a first display 12 such that they face the first display surface 11, and, further, there is placed a camera 91 such that it faces the photographing lens 9. Further, the first casing 1 houses therein a battery 15, such that replacement of the battery 15 can be performed, by removing a battery lid 14.

On the other hand, inside the second casing 2, there are placed a second touch panel 23 and a second display 22, such that they face the second display surface 21.

On the surface of the first touch panel 13, there is placed a glass plate 16 which is wider than the first display 12 and the first touch panel 13, and a surface of the glass plate 16 forms the first display surface 11 to display thereon images in the first display 12.

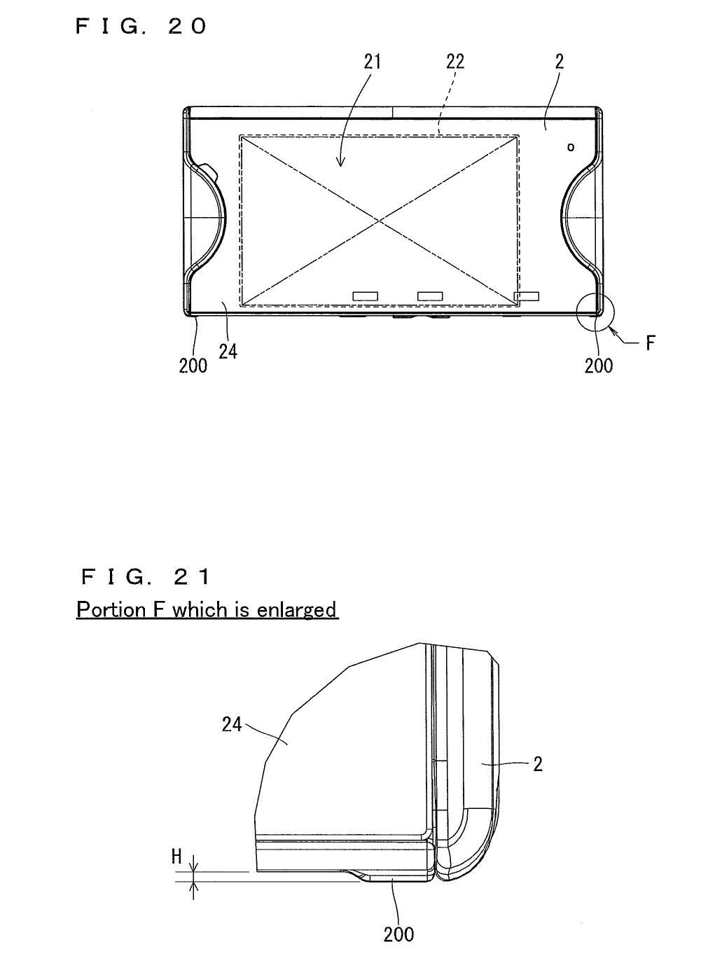

Further, on the surface of the second touch panel 23, there is placed a glass plate 24 which is wider than the second display 22 and the touch panel 23, and a surface of the glass plate 24 forms the second display surface 21 to display thereon images in the second display 22 (see FIG. 20).

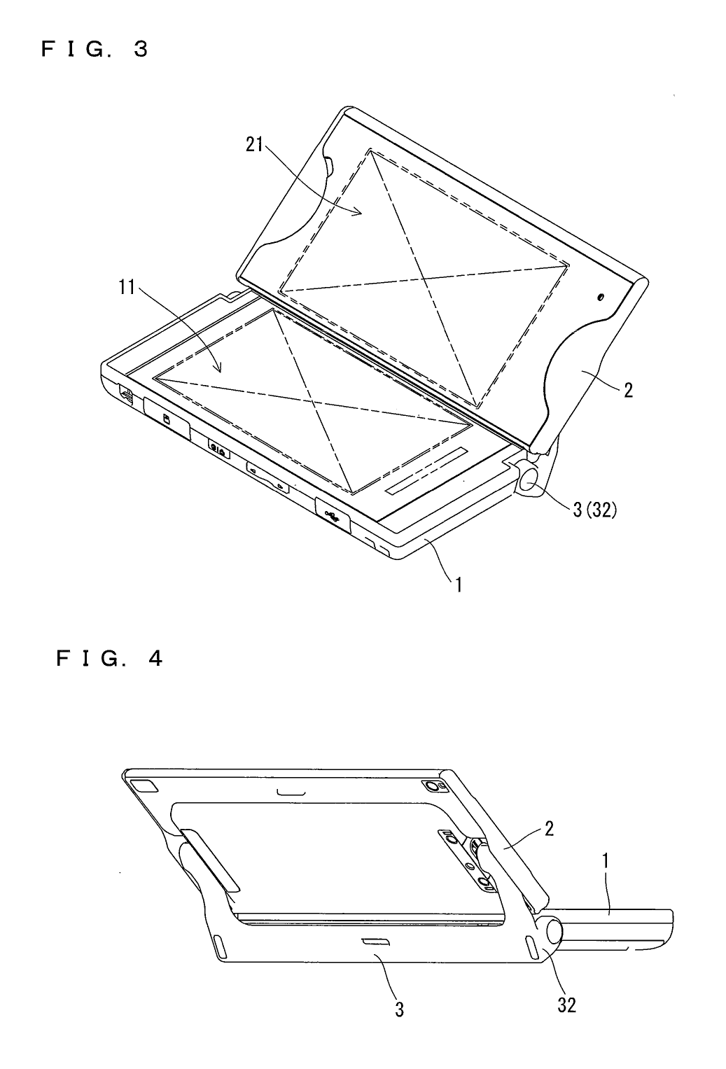

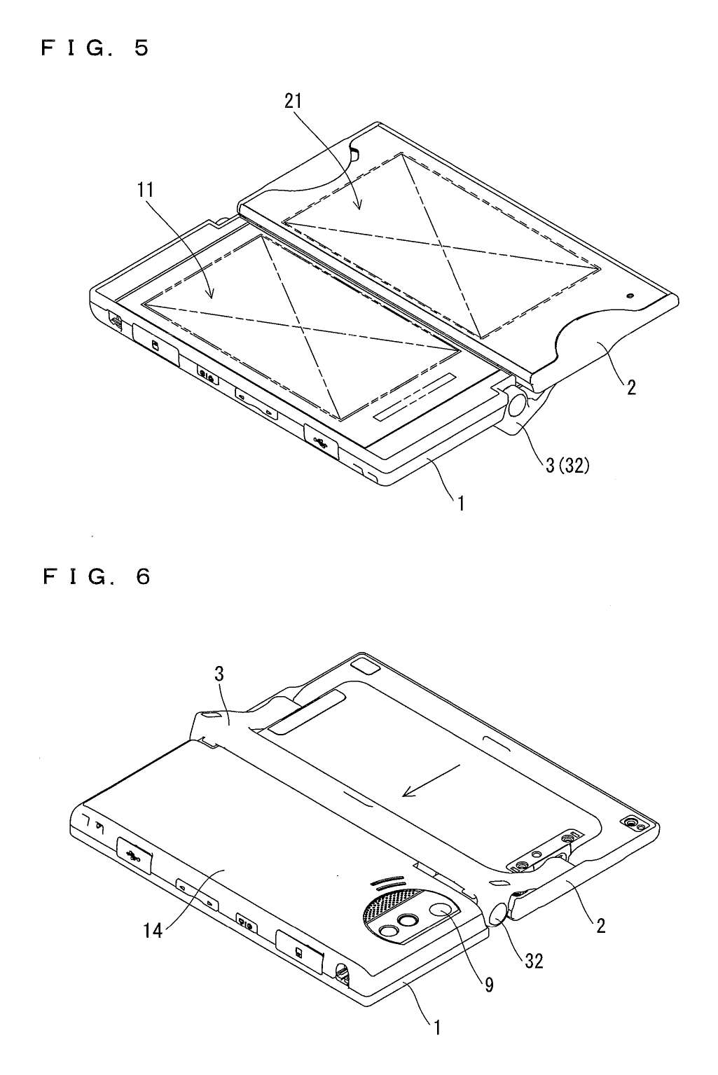

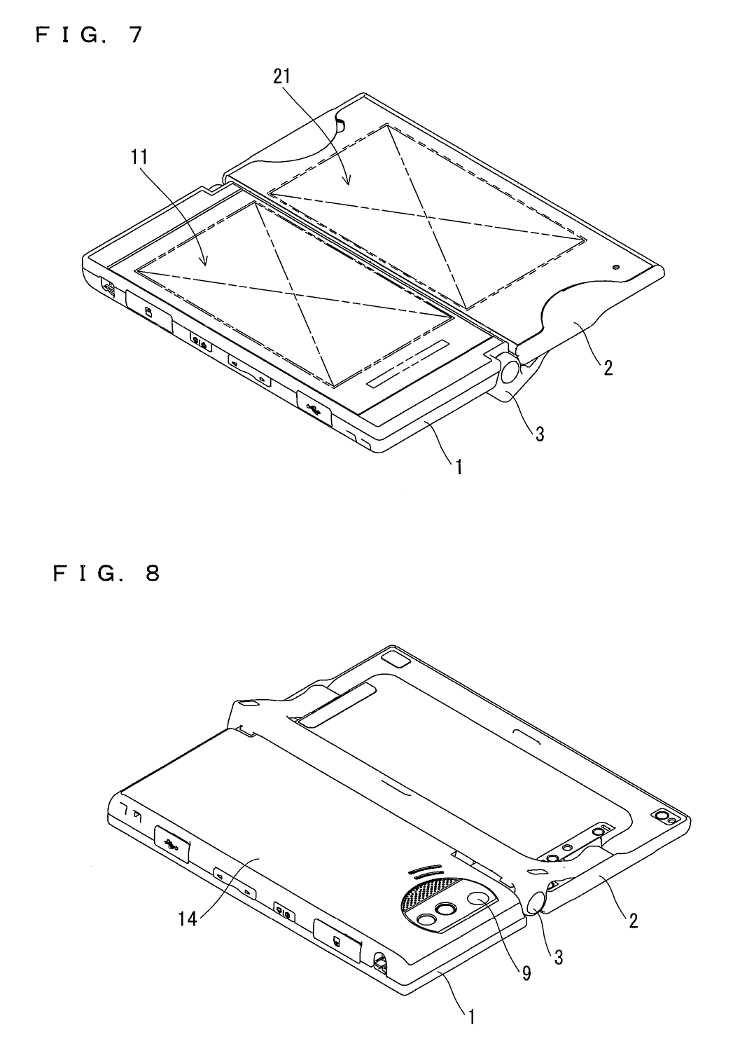

The portable electronic apparatus according to the present invention is capable of being selectively set in four states as follows: a closed state where the first casing 1 is covered at its surface with the rear surface of the second casing 2 and, also, the surface of the second casing 2 is exposed as illustrated in FIG. 1 and FIG. 2; a tilt state where the second casing 2 has been rearwardly moved so that the surfaces of the both the casings 1 and 2 are exposed and, also, the surface of the second casing 2 is inclined with respect to the surface of the first casing 1 at an angle of opening which is equal to or more than 90 degrees but less than 180 degrees as illustrated in FIG. 3 and FIG. 4; a first open state where the second casing 2 has been rearwardly rotated so that the surfaces of both the casings 1 and 2 are exposed in the same plane as illustrated in FIG. 5 and FIG. 6; and a second open state where the second casing 2 has been slid toward the first casing 1 in a state where the surfaces of both the casings 1 and 2 are exposed in the same plane as illustrated in FIG. 7 and FIG. 8.

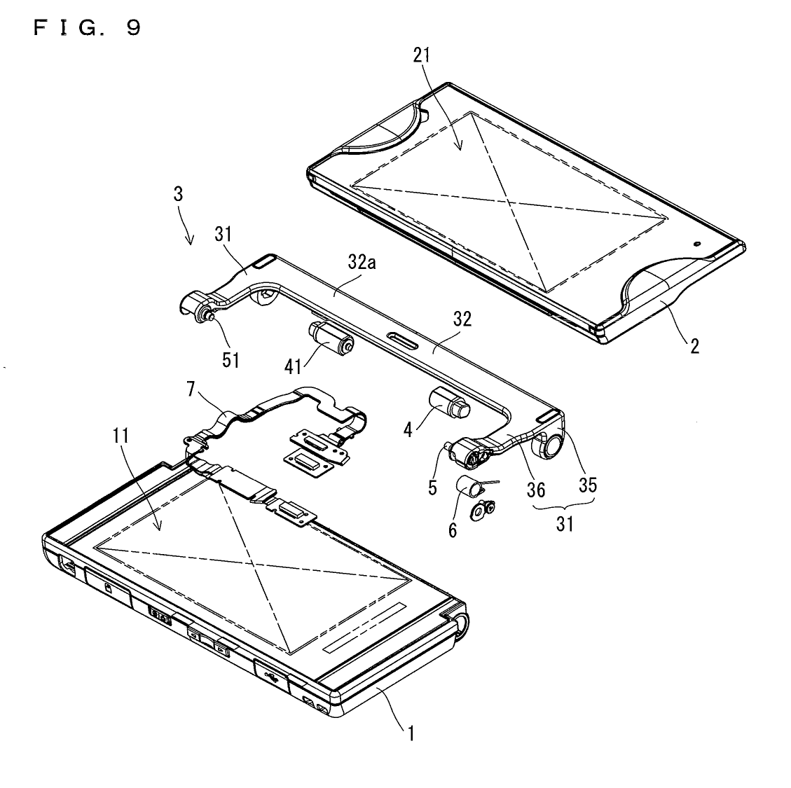

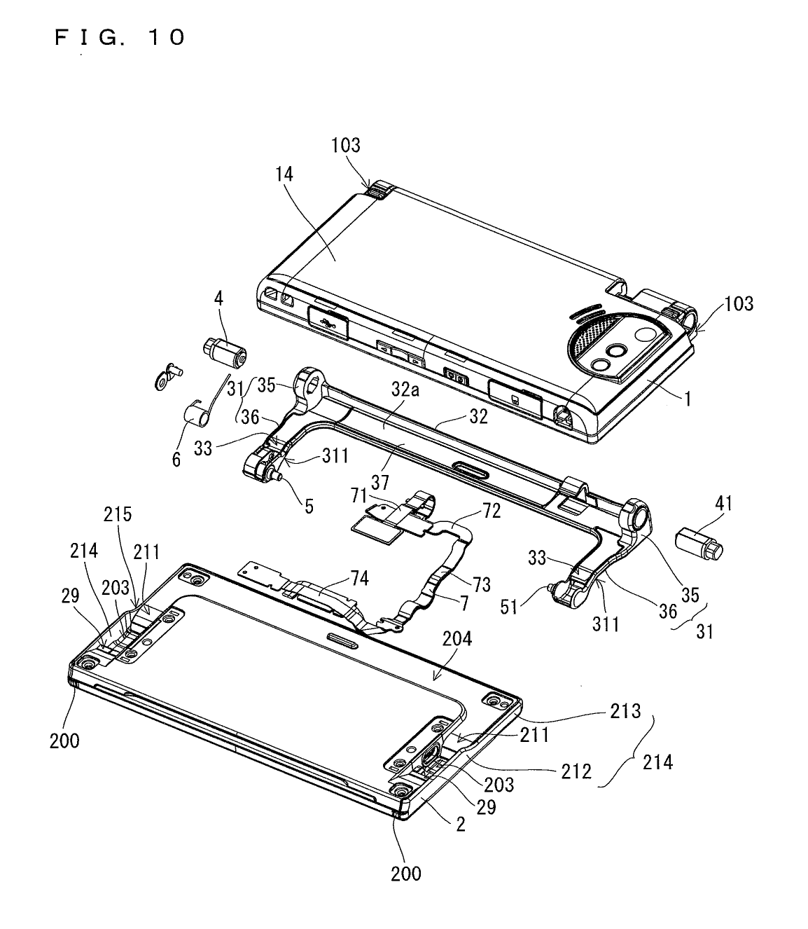

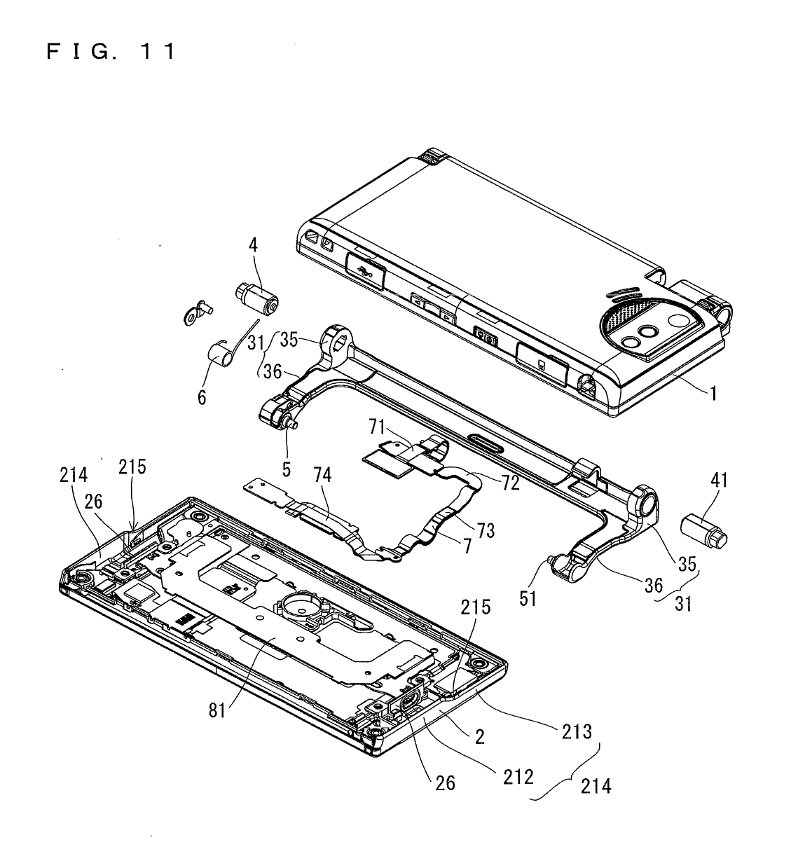

The coupling mechanism 3 which couples the first casing 1 and the second casing 2 to each other includes a U-shaped coupling member 32 constituted by protruding a pair of left and right coupling arms 31 and 31 extended in the forward and rearward directions at both ends of an arm coupling portion 32a extended leftward and rightward as illustrated in FIG. 9 and FIG. 10.

The coupling arm 31 takes an L shape which is bent in the L shape over an orthogonal plane to the display surfaces of both the casings and is constituted by a first arm portion 35 and a second arm portion 36 which intersect with each other at an angular portion of the L shape.

The right coupling arm 31 is coupled at its base end portion (the base end portion of the first arm portion 35) to the rear end portion of the right side surface of the first casing 1 through a well-known type hinge unit 4 incorporating a spring and a cam mechanism. The left coupling arm 31 is coupled at its base end portion (the base end portion of the first arm portion 35) to the rear end portion of the left side surface of the first casing 1 through a dummy hinge unit 41 incorporating neither a spring nor a cam mechanism.

Further, the right coupling arm 31 is coupled at its tip end portion (the tip end portion of the second arm portion 36) to the right end portion of the rear surface of the second casing 2 through a first hinge member 5. The left coupling arm 31 is coupled at its tip end portion (the tip end portion of the second arm portion 36) to the left end portion of the rear surface of the second casing 2 through a second hinge member 51.

The hinge units 4 and 41 form a first pivot shaft which couples the base end portions of the coupling arms 31 to the first casing 1, while the hinge members 5 and 51 form a second pivot shaft which couples the tip end portions of the coupling arms 31 to the second casing 2, such that the first pivot shaft and the second pivot shaft are parallel to each other.

Further, the second arm portions 36 of the respective coupling arms 31 are provided with abutting surfaces 311 at their portions facing the second casing 2 and, also, the second casing 2 is provided with abutting receiving surfaces 211 to receive the abutting surfaces 311 in the closed state.

The electronic components incorporated in the first casing 1 and the electronic components incorporated in the second casing 2 are connected to each other through a flexible lead 7. The flexible lead 7 extends from the inside of the first casing 1 to the inside of the second casing 2 through the inside of a coupling arm 31. Further, the flexible lead 7 includes a first lead portion 71 housed within the first casing 1, a second lead portion 72 housed within the coupling arm 31, and a third lead portion 73 housed within the second casing 2.

Further, the flexible lead 7 has a minimum extra length which allows the first casing 1 and the second casing 2 to move relative to each other.

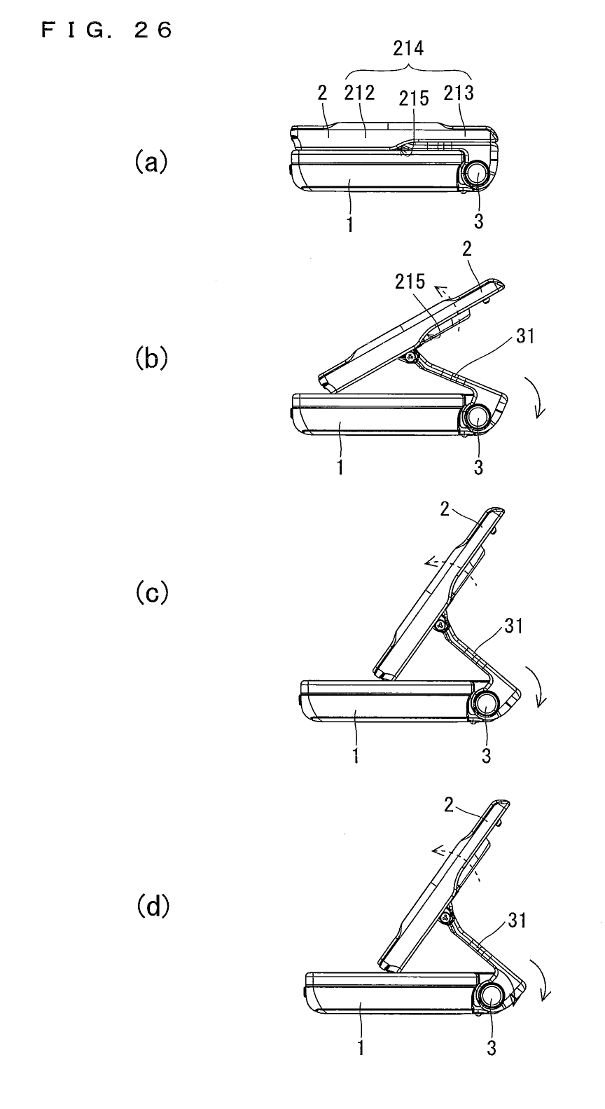

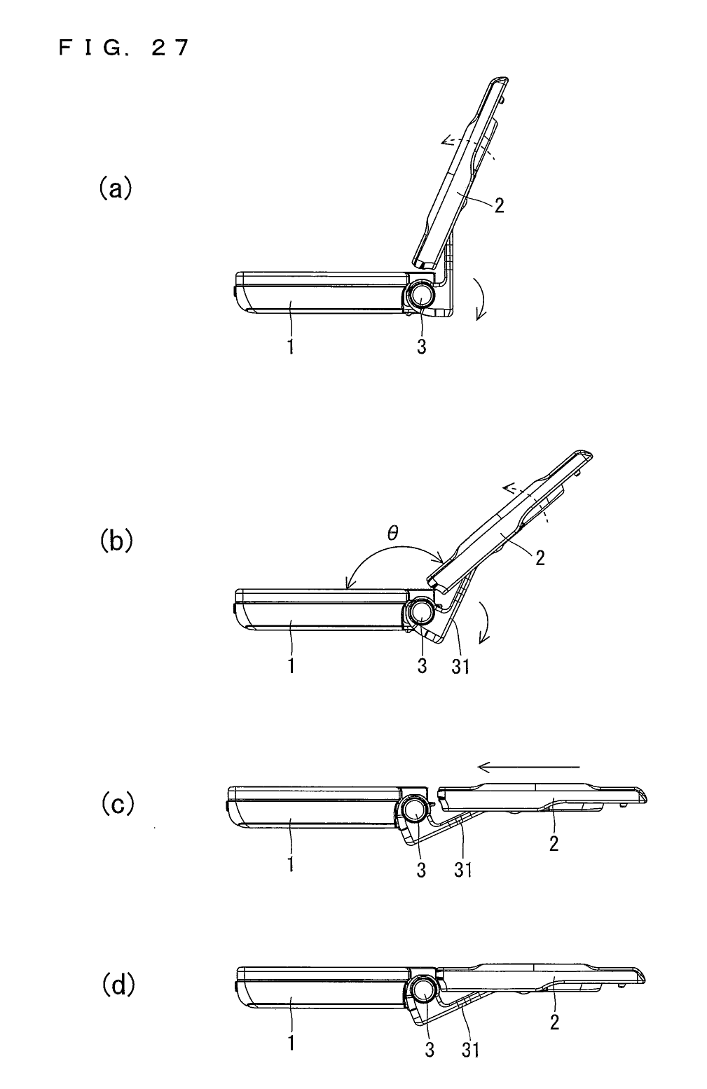

Consequently, the second casing 2 can carry out a series of movements relative to the first casing 1 as illustrated in FIGS. 26A to 26D and FIGS. 27A to 27D.

In the tilt state illustrated in FIG. 3 and FIG. 4, the hinge unit 4 softly locks the coupling member 32 with respect to the first casing 1 and, also, biases the coupling member 32 toward the rotational angle of the tilt state, within a certain angle range centered at the rotational angle of the tilt state. Further, the hinge unit 4 biases the coupling member 32 toward the rotational angle of the first open state, within a certain angle range including the rotational angle of the first open state illustrated in FIG. 5 and FIG. 6.

Further, in the first open state illustrated in FIG. 5 and FIG. 6, the coupling member 32 is received by the first casing 1, so that the coupling member 32 is held at the rotational angle of the first open state.

As illustrated in FIG. 9, a torsion spring 6 is attached to the first hinge member 5 around a rotating shaft (the second pivot shaft) thereof, and the torsion spring 6 biases the second casing 2 to be rotated in such a direction as to reduce an opening angle θ in the tilt state illustrated in FIG. 27B.

Further, as illustrated in FIG. 10, the first casing 1 is provided at the rear end portions of its opposite side surfaces with housing portions 103 and 103 with concave shapes to house the first arm portions 35 and 35 of the coupling arms 31 and 31 of the coupling member 32.

On the other hand, the second casing 2 is provided at the opposite side portions of its rear surface with housing portions 204, 203 and 203 with concave shapes to house the arm coupling portion 37 and the second arm portions 36 and 36 of the coupling member 32.

Both sidewalls 214 and 214 of the second casing 2 include a first sidewall portion 212 having a great height from the surface of the second casing 2 toward the first casing 1 side and a second sidewall portion 213 having a small height from the surface of the second casing 2 toward the first casing 1 side in the closed state respectively, and a pair of left and right first sidewall portions 212 and 212 are positioned on both sides of the housing portions 203 and 203 at both sides of the second casing 2.

Moreover, a finger putting surface 215 inclined to the surface of the first casing 1 in the closed state is formed between an end surface of the first sidewall portion 212 and that of the second sidewall portion 213 which are faced to the surface of the first casing 1.

Further, as illustrated in FIG. 10, both the coupling arms 31 and 31 of the coupling member 32 are provided with respective receiving surfaces 33 for receiving the second casing 2 at their portions facing the second casing 2 and, also, the second casing 2 is provided at the opposite end portions of its rear surface with respective sliding surfaces 29 to slidably come into contact with the receiving surfaces 33.

In the tilt state illustrated in FIG. 3 and FIG. 4 and in the first open state illustrated in FIG. 5 and FIG. 6, the sliding surfaces 29 in the second casing 2 come into contact with the receiving surfaces 33 in the coupling arm 31 to receive the rotation of the second casing 2 with respect to the coupling arms 31, so that the attitude of the second casing 2 with respect to the coupling arms 31 is defined in the tilt state and in the first open state.

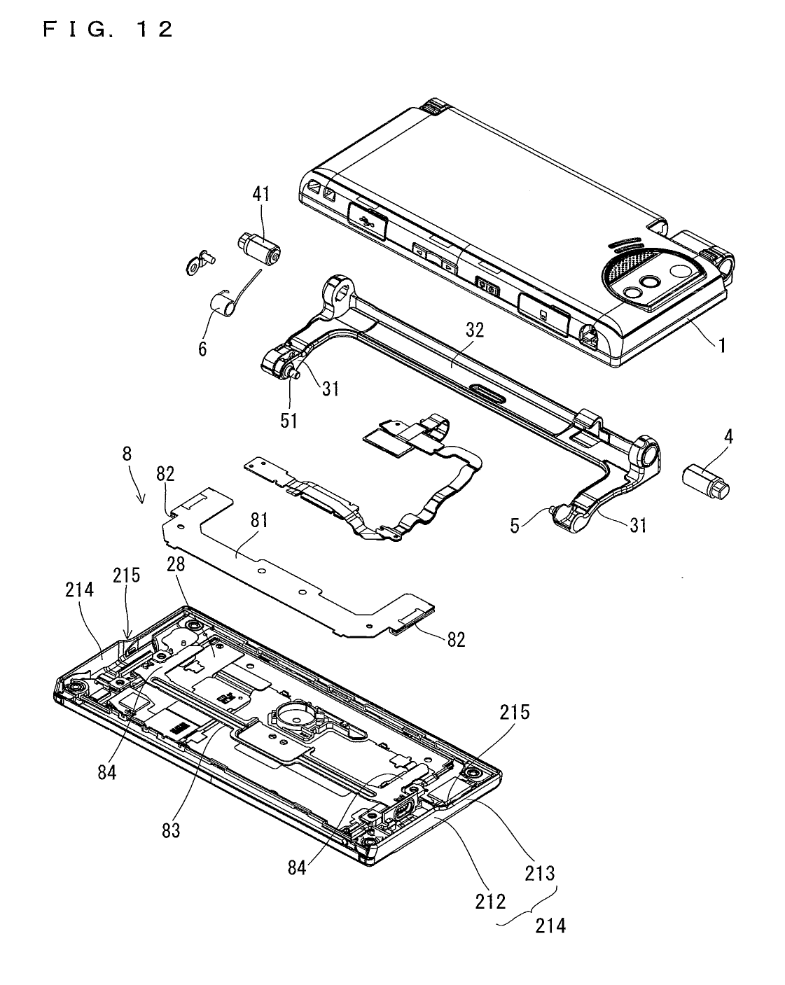

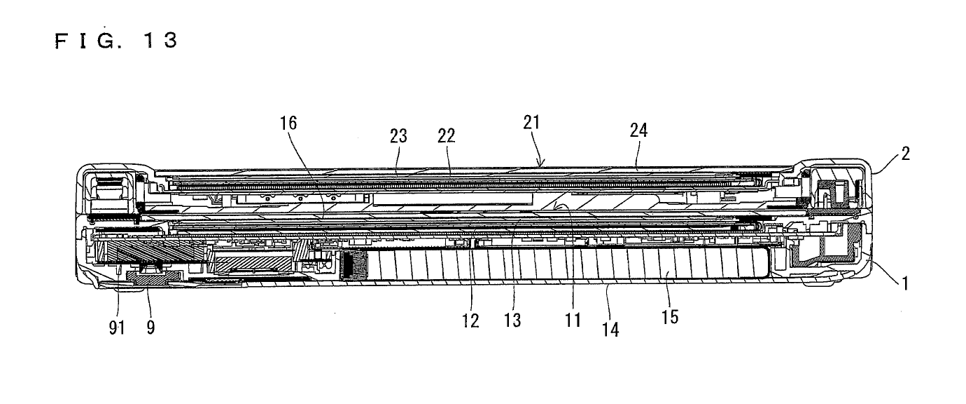

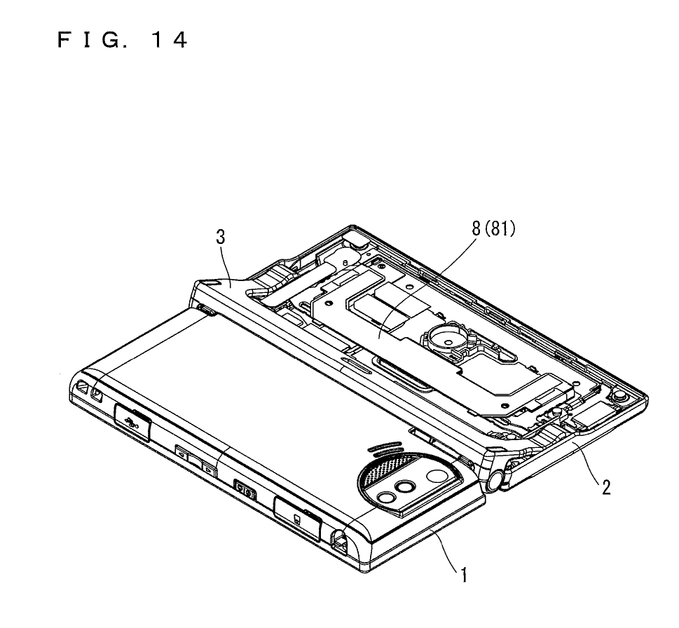

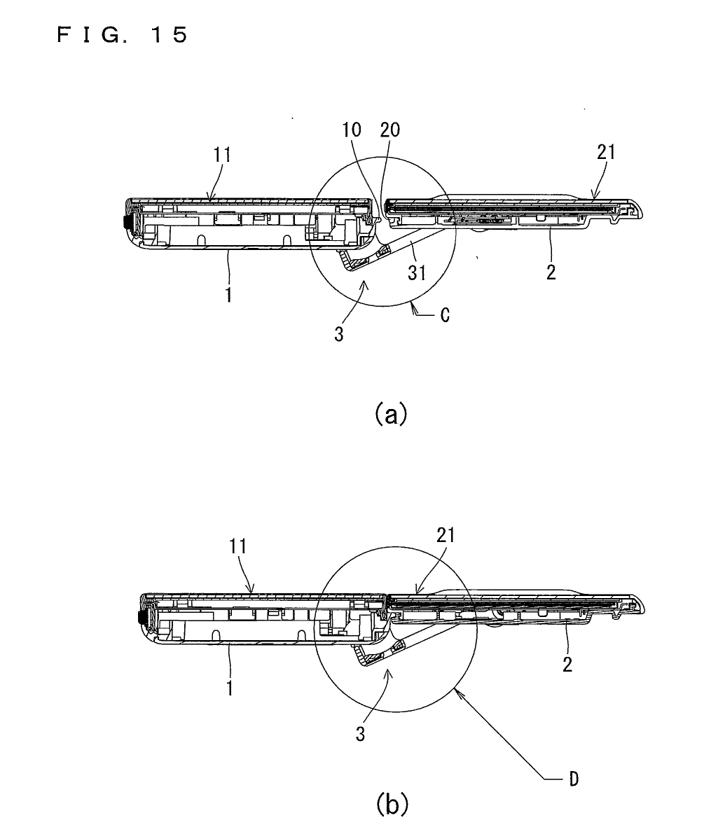

As illustrated in FIG. 12, a U-shaped sliding member 83 which is slidable forwardly and rearwardly is provided on a sheet metal member 28 disposed in the second casing 2, and furthermore, a U-shaped supporting member 81 is fixed to cover the sliding member 83 (see FIG. 14).

As illustrated in FIG. 12, the sliding member 83 is provided with arm portions 84 and 84 protruding from its opposite end portions in the left and right sides. Further, slidable guide members 82 and 82 are mounted to the supporting member 81 at its opposite end portions in the left and right sides.

Further, the arm portions 84 and 84 of the sliding member 83 are sandwiched between the sheet metal member 28 and the slidable guide members 82 and 82 of the supporting member 81, so that the sliding of the sliding member 83 in the forward and rearward directions on the sheet metal member 28 is guided.

The first hinge member 5 and the second hinge member 51 which have been described above are pivotally coupled at their respective tip end portions to the opposite side portions of the arm portions 84 and 84 of the sliding member 83.

Accordingly, there is structured a sliding mechanism 8 for sliding the second casing 2 in the forward and rearward directions with respect to the arm portions 84 and 84 of the sliding member 83, so that the second casing 2 is enabled to slide forwardly and rearwardly, between the first open state illustrated in FIG. 5 and FIG. 6 and the second open state illustrated in FIG. 7 and FIG. 8.

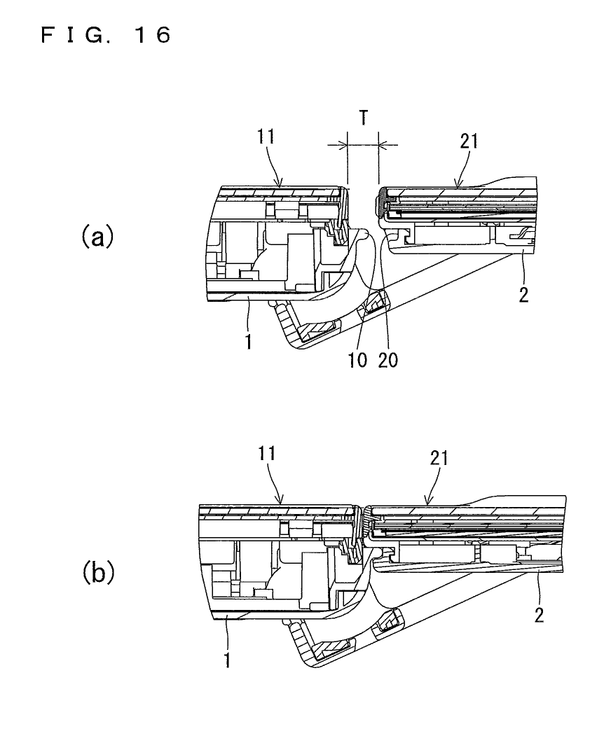

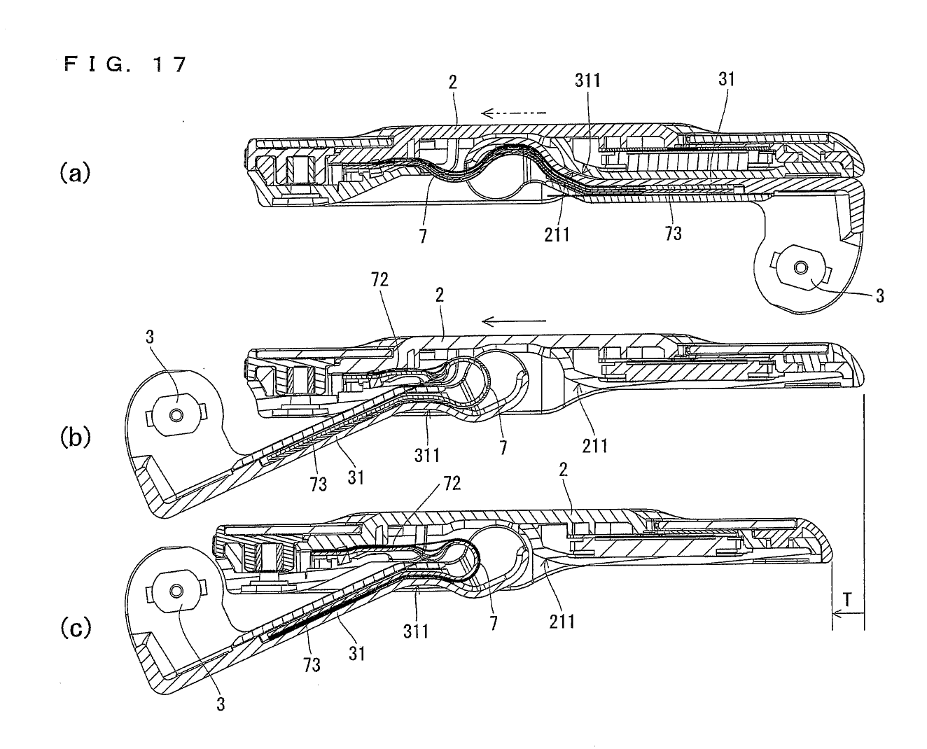

The rear end surface of the first casing 1 and the front end surface of the second casing 2 which are faced to each other in the first open state are provided with a convex portion 10 and a concave portion 20 respectively, which can be engaged with and disengaged from each other as illustrated in FIGS. 15A and 15B and FIGS. 16A and 16B. The convex portion 10 and the concave portion 20 are disengaged from each other in the first open state illustrated in FIGS. 15A and 16A, and the convex portion 10 and the concave portion 20 are engaged with each other in the second open state illustrated in FIGS. 15B and 16B.

As a result, in the second open state illustrated in FIGS. 15B and 16B, the first casing 1 and the second casing 2 are coupled to each other through the engagement between the convex portion 10 and the concave portion 20 so that the first display surface 11 and the second display surface 21 are maintained at a state where the first display surface 11 and the second display surface 21 are flushed with each other in the same plane.

In the first open state illustrated in FIGS. 15A and 16A, a gap T having a sufficient size (for example, several mm) is provided between the first casing 1 and the second casing 2. However, in the second open state illustrated in FIGS. 15B and 16B, the first casing 1 and the second casing 2 come into contact with each other or are faced to each other at a slight distance (for example, 0.1 mm) interposed therebetween.

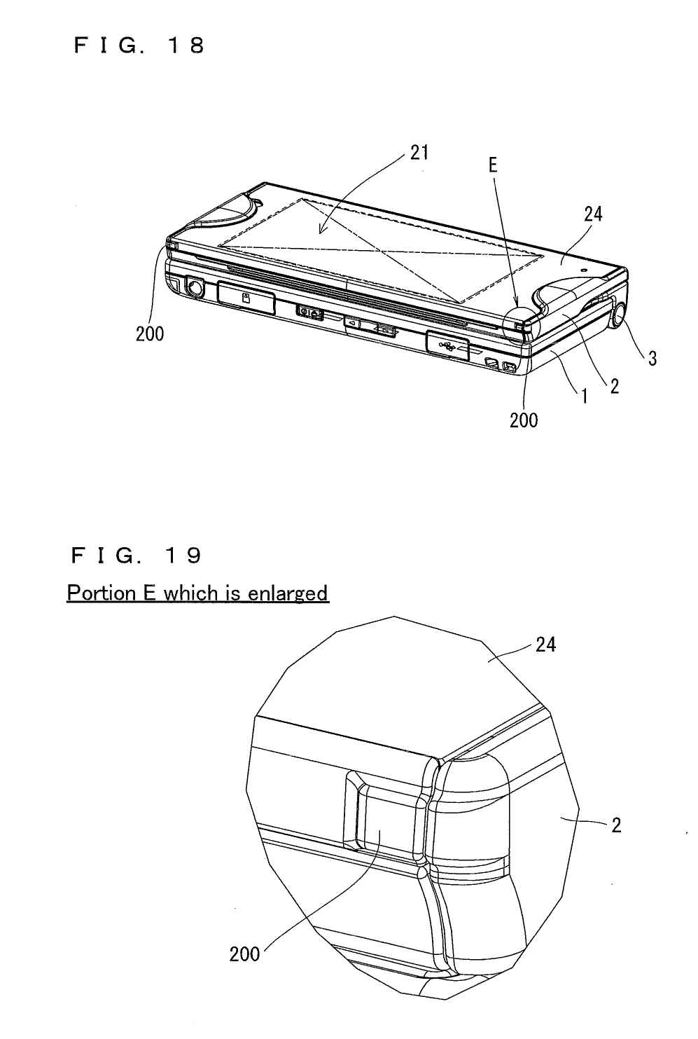

Further, in the portable electronic apparatus, as illustrated in FIGS. 18 to 21, the first casing 1 is provided with a pair of convex portions 200 and 200 at the opposite end portions of its front end surface in the left and right side thereof. A height H of the protrusion of the convex portion 200 is about 0.3 mm.

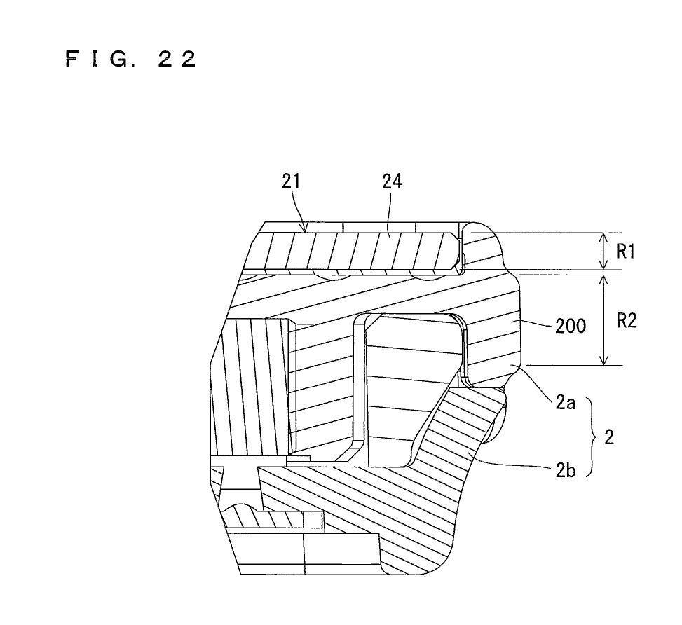

More specifically, as illustrated in FIG. 22, the second casing 2 is constituted by a front-surface cabinet 2a and a rear-surface cabinet 2b which are made of synthetic resins respectively, and the pair of convex portions 200 and 200 are formed in the front-surface cabinet 2a and are disposed in an area R2 which is deviated from a thickwise area R1 of the glass plate 24 of the front-surface cabinet 2a with respect to the glass plate 24, and at a position deviated in the widthwise direction of the second display 22 from the display 22 as illustrated in FIG. 20.

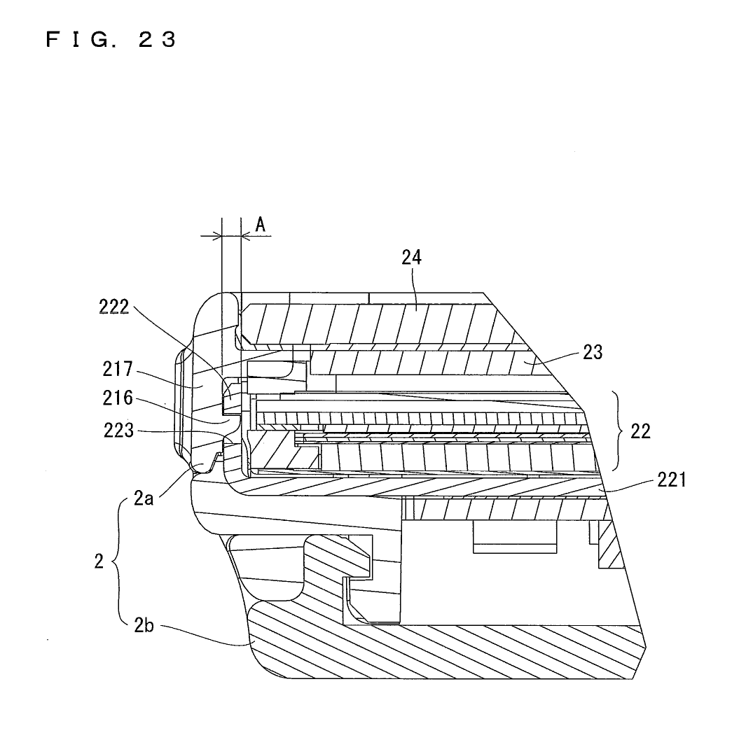

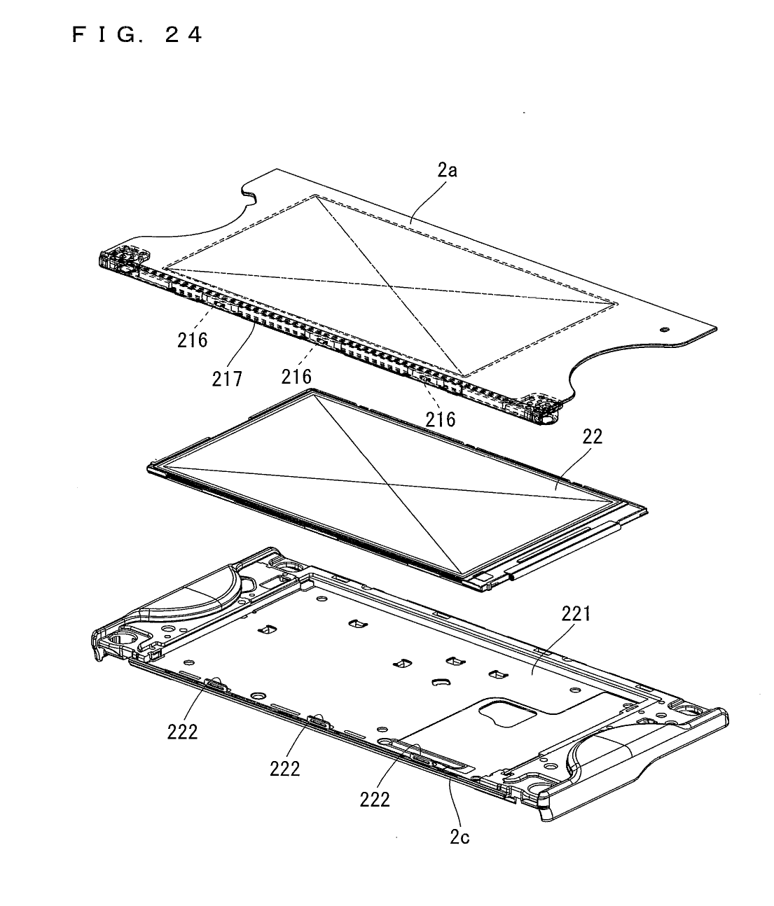

As shown in FIGS. 23 and 24, moreover, the second display 22 is held on a holder member 221 constituted by a sheet metal (a metal thickness of 0.3 mm) made of a stainless steel, and the holder member 221 is engaged with the front-surface cabinet 2a of the second casing 2.

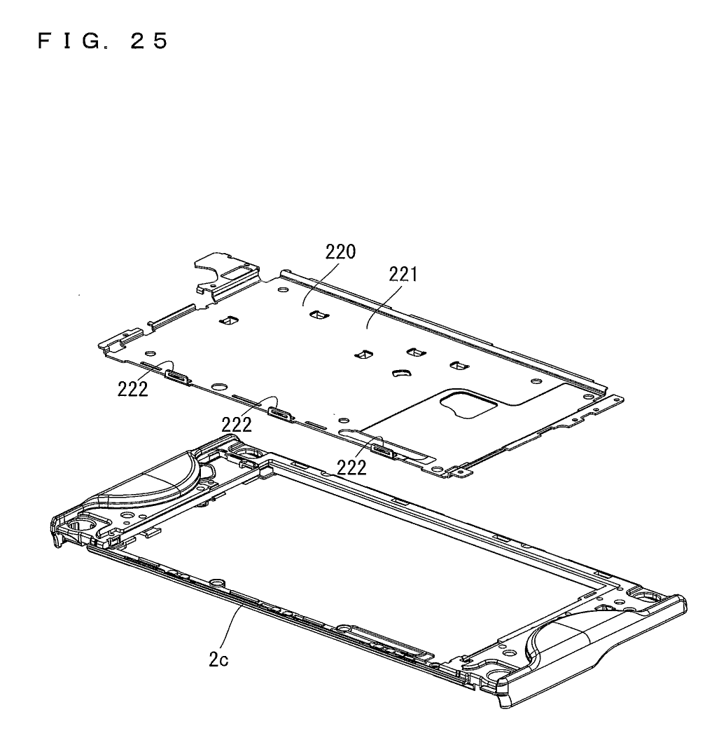

More specifically, the holder member 221 is engaged with a frame-shaped frame member 2c made of a synthetic resin illustrated in FIG. 25, and three engaged pieces 222, 222 and 222 are protruded upward from an edge on the forward side of a flat plate portion 220 on which the second display is to be mounted.

On the other hand, as shown in FIGS. 23 and 24, a sidewall 217 extended along the edge on the forward side of the second display 22 is formed in the front-surface cabinet 2a of the second casing 2, and three engaging pieces 216, 216 and 216 to be engaged with the three engaged pieces 222, 222 and 222 are protruded toward the second display 22 on an internal surface of the sidewall 217.

As shown in FIG. 23, in the engaging state of the engaged piece 222 and the engaging piece 216, the engaging piece 216 is fitted in a hole 223 formed on the engaged piece 222 so that the holder member 221 is engaged with the front-surface cabinet 2a of the second housing 2.

For example, an engagement depth (the plate thickness of the holder member 221) A of the engaging piece 216 and the engaged piece 222 is set to be 0.3 mm.

The portable electronic apparatus is capable of being selectively set in four states as follows: the closed state where the first casing 1 and the second casing 2 are overlaid on each other such that only the second display surface 21 is exposed as illustrated in FIG. 1 and FIG. 2; the tilt state where the second casing 2 has been rearwardly moved from the closed state so that both the first display surface 11 and the second display surface 21 are exposed and, also, the second display surface 21 is inclined with respect to the first display surface 11 at an angle of opening which is equal to or more than 90 degrees but less than 180 degrees as illustrated in FIG. 3 and FIG. 4; the first open state where the second casing 2 has been rearwardly rotated from the tilt state so that both the first display surface 11 and the second display surface 21 are exposed in the same plane as illustrated in FIG. 5 and FIG. 6; and the second open state where the second casing 2 has been slid toward the first casing 1 from the first open state, and both the display surfaces 11 and 21 are exposed in the same plane at positions where the first display surface 11 and the second display surface 21 are closer to each other as illustrated in FIG. 7 and FIG. 8.

In the closed state illustrated in FIG. 1 and FIG. 2, the first arm portions 35 and 35 of the coupling arms 31 and 31 are housed in the housing portions 103 and 103 in the first casing 1 illustrated in FIG. 10 and, also, the arm coupling portion 37 and the second arm portions 36 and 36 of the coupling member 32 are housed in the housing portions 204, 203 and 203 in the second casing 2, so that the coupling mechanism 3 is not protruded from the opposite side surfaces and the rear end surfaces of both the casings 1 and 2 and, thus, the entire apparatus is compacted.

Further, in the closed state, as illustrated in FIG. 18, the front end surface of the first casing 1 and the front end surface of the second casing 2 are aligned, and the convex portions 200 and 200 are protruded forwardly from the front end surfaces of both the casings 1 and 2.

In any of the tilt state illustrated in FIG. 3, the first open state illustrated in FIG. 5 and the second open state illustrated in FIG. 7, the coupling mechanism 3 is hidden substantially in its entirety behind the rear surfaces of both the casings 1 and 2 and it is hard to see the protruding portion of the coupling mechanism 3 along a usual user's line of sight (the arrow S in FIG. 1).

Further, in the second open state, the first arm portions 35 and 35 of the coupling arms 31 and 31 in the second casing 2 are housed in the housing portions 103 and 103 in the first casing 1 illustrated in FIG. 10 and, further, the convex portions 200 and 200 in the second casing 2 are also housed therein.

As illustrated in FIGS. 26A to 26D and FIGS. 27A to 27D, in a process for a transition of the portable electronic apparatus from the closed state to the second open state through the tilt state and the first open state, if the second casing 2 is pushed rearwardly to be slightly moved in the closed state illustrated in FIG. 18A, the second casing 2 is thereafter rotated in a counterclockwise direction as indicated by a broken-line arrow due to the biasing by the torsion spring 6 and, along therewith, the coupling arms 31 are rotated in a clockwise direction as indicated by a solid-line arrow as illustrated in B to D in the same figure.

Thus, the second casing 2 is rearwardly moved, while the second display surface 21 is kept oriented upwardly or obliquely upwardly.

In the case in which the second casing 2 is opened from the closed state illustrated in FIG. 18A to the opened state illustrated in FIG. 18B, it is also possible to carry out an operation for lifting the second casing 2 up to an oblique attitude in a state in which the first casing 1 is held by one of hands and fingertips of the other hand are put on both side portions of the second casing 2 to interpose the casing 2 by the other hand.

In this case, the tip portion (the portion coupled to the second casing) of the coupling arm 31 is covered with the first sidewall portion 212 of the sidewall 214 in the second casing 2 as illustrated in FIG. 26A. Therefore, the fingertips of the hand which interpose the second casing 2 come in contact with both of the sidewalls 214 and 214 of the second casing 2 so that the fingertips can reliably interpose the second casing 2 without feeling a pain.

In particular, the finger putting surface 215 is formed between the end surface of the first sidewall portion 212 and that of the second sidewall portion 212. Therefore, when the second casing 2 is to be interposed with the fingertips of the hand in the closed state, it is possible to put the fingertips on the finger putting surface 215. Consequently, it is possible to reliably lift the second casing 2.

Then, at a time point slightly after the state of FIG. 26D, the coupling arms 31 are further rotated in the clockwise direction due to the biasing by the hinge unit 4 as in FIG. 27A, and thereafter, are softly locked at the rotational angle in the tilt state as in B in the same figure. Further, the second casing 2 is rotated in the counterclockwise direction due to the biasing by the torsion spring 6 and the sliding surface 29 comes into contact with the receiving surface 33 of the coupling arm 31 so that the second casing 2 is thus held in the attitude in the tilt state illustrated in FIG. 27B.

Accordingly, if the user merely pushes the second casing 2 rearwardly in the closed state illustrated in FIG. 26A to slightly move it, then, the second casing 2 automatically moves into the tilt state illustrated in FIG. 27B.

Next, if the second casing 2 is pushed rearwardly to slightly rotate the coupling arms 31 in the clockwise direction in the tilt state illustrated in FIG. 27B, the coupling arms 31 are then rotated to the rotational angle in the first open state illustrated in FIG. 27C due to the biasing by the hinge unit 4 and are received by the first casing 1 at this rotational angle with the sliding surface 29 of the second casing 2 being kept in contact with the receiving surface 33 of the coupling arms 31.

Along with this rotation of the coupling arms 31, the second casing 2 is rearwardly rotated and, finally, the first display surface 11 and the second display surface 21 are aligned in the same plane.

Further, if the second casing 2 is pulled toward the first casing 1 side in the first open state illustrated in FIG. 27C, the sliding surfaces 29 in the second casing 2 slide over the receiving surfaces 33 in the coupling arms 31 so that the second casing 2 horizontally moves to a second open position illustrated in FIG. 27D and finally comes into contact with the first casing 1.

As a result thereof, as illustrated in FIG. 7, the first display surface 11 and the second display surface 21 get closer to each other, so that both the display surfaces 11 and 21 form a single large screen.

In the second open state, as illustrated in FIG. 15B, the convex portion 10 in the first casing 1 and the concave portion 20 in the second casing 2 are engaged with each other so that both the casings 1 and 2 are coupled to each other. Accordingly, even if an operation for strongly touching the second display surface 21 is performed in this state, the second casing 2 is maintained at a certain attitude with respect to the first casing 1.

FIGS. 17A to 17C illustrate states of bendings and deformations of the flexible lead 7 in a process from the closed state to the second open state via the first open state.

In the closed state illustrated in FIG. 17A, as described above, the abutting surfaces 311 formed in the second arm portions 36 of the coupling arms 31 and the abutting receiving surfaces 211 formed in the second casing 2 come into contact with each other so that the second casing 2 is prevented from sliding in the direction indicated by an arrow shown in a two-dotted chain line.

Next, in the first open state illustrated in FIG. 17B, along with the rotation of the coupling arms 31, the flexible lead 7 is largely bent and deformed between the second lead portion 72 and the third lead portion 73.

Further, the second casing 2 is caused to slide forward (leftward in the figure) by a distance T from the state illustrated in FIG. 17B as indicated by an arrow in the figure, resulting in the second open state illustrated in FIG. 17C. During this processing, the flexible lead 7 is forwardly displaced, by further increasing the curvature in its bending portion between the second lead portion 72 and the third lead portion 73.

In the portable electronic apparatus, in the closed state illustrated in FIG. 17A, the second casing 2 is prevented from moving in the direction indicated by the chain-line arrow in the figure. Therefore, it is possible to reduce a length of the flexible lead 7 by an extra length to be given to the flexible lead 7 if the second casing 2 slides by the operation of the sliding mechanism 8.

Accordingly, the flexible lead 7 can be formed in a length in consideration of only the bendings and deformations of the flexible lead (7) along with the rotation of the coupling arms 31 illustrated in FIGS. 17A to 17C. Consequently, it is possible to minimize the looseness of the flexible lead 7 in the closed state illustrated in FIG. 17A.

In the portable electronic apparatus, as shown in FIG. 23, the engaging piece 216 is protruded integrally with the front-surface cabinet 2a made of a synthetic resin, and furthermore, the engaged piece 222 is protruded integrally with the holder member 221 made of a stainless steel. Therefore, the engaging piece 216 made of a synthetic resin and the engaged piece 222 made of a stainless steel are engaged with each other.

The hook structure constituted by the engaging piece made of a synthetic resin and the engaged piece made of a stainless steel is also employed for the engagement of the first display 12 in the first casing 1.

As compared with the conventional structure in which both the engaging piece and the engaged piece that are made of synthetic resins, accordingly, a gap between the first display 12 and the second display 22 in the opened state is reduced by a decrement of a plate thickness with a change of the material of the engaged piece from a synthetic resin to a stainless steel (approximately 1.0 mm at both of the first and second casing sides in the example described above).

In the case in which both of the display surfaces 11 and 21 are set as a single screen to display a large image with the two display surfaces 11 and 21 aligned over the same plane with each other (the second open state) as shown in FIG. 7, it is possible to implement an excellent image display with a slight breakage.

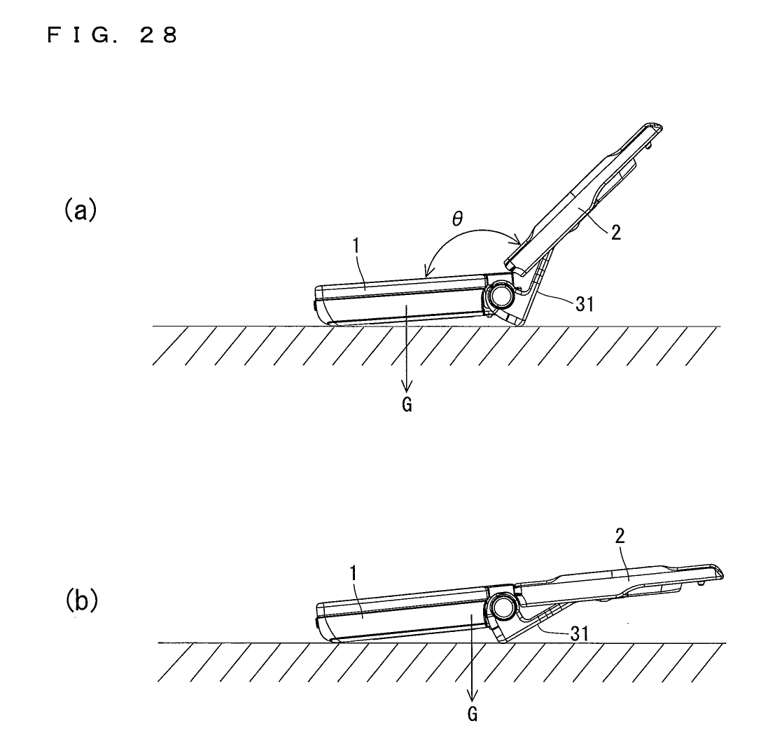

When the portable electronic apparatus is placed on a desk in the tilt state as illustrated in FIG. 28A or when it is placed on a desk in the second open state as illustrated in FIG. 28B, the angular portions of the coupling arms 31 are protruded from the rear surface of the first casing 1 so that the front end of the first casing 1 and the angular portions of the coupling arms 31 are grounded.

The replacement of the components with respect to the first casing 1 and the second casing 2 and the L shape of the coupling arm 31 are designed in such a manner that a center of gravity G is positioned on the first casing 1 side with respect to the grounded points of the coupling arms 31 as illustrated in the figure in any state. This enables stabilization of the attitudes of both the casings 1 and 2.

Accordingly, when it is placed on a desk in the tilt state as illustrated in FIG. 28A, it is possible to operate the touch panel of the first casing 1 in the front part while viewing the display of the second casing 2 in the rear part, for example.

Further, when it is placed on a desk in the second open state as illustrated in FIG. 28B, both of the display surfaces 11 and 21 take such attitudes as to be slightly oriented toward the user side depending on the amount of the protrusion of the angular portions of the coupling arms 31 and, for example, both of the display surfaces 11 and 21 form a single screen to enable images to be viewed through the large screen. In this case, both the display surfaces 11 and 21 are sufficiently close to each other, which enables displaying images with substantially no discontinuities, on both the display surfaces 11 and 21.

Furthermore, with the portable electronic apparatus, in the event that the apparatus is fallen onto a floor surface, if the apparatus, during the falling, takes such an attitude that the front end surface of the second casing 2 faces downwardly, any one convex portion 200, out of the pair of the convex portions 200 and 200 formed in the front end surface, impinges on the floor surface at first and, immediately thereafter, the other convex portion 200 impinges on the floor surface.

In this case, as illustrated in FIG. 20, the second display 22 is placed such that it is as close to the front end surface of the second casing 2 as possible, and the glass plate 24 is placed such that it covers the second display 22. Accordingly, there is a significantly small distance between the front end surface of the glass plate 24 and the front end surface of the second casing 2. Thus, if an impulsive force acts on the front end surface of the second casing 2, this impulsive force may be transmitted to the glass plate 24, thereby causing a fracture of the glass plate 24.

However, in the portable electronic apparatus, the pair of the convex portions 200 and 200 are placed at positions which are deviated from the glass plate 24 in the second casing 2 in the thickwise direction and, also, are deviated from the second display 22 in the widthwise direction, so that these convex portions 200 exert their shock absorption effects depending on their height. Therefore, in comparison with cases where an apparatus impinges on a floor surface at its front end surface provided with no such convex portions 200, it is possible to largely reduce the impulsive force acting on the second display 22 and on the glass plate 24 covering the second display 22.

As a result thereof, it is possible to suppress the occurrence of fractures of the second display 22 and the glass plate 24 due to effects of such impulsive forces.

Further, an impulsive force may act on the glass plate 16 in the first casing 1 due to falling thereof. However, in the closed state, the first casing 1 is covered at its rear end surface with the coupling member 32 illustrated in FIG. 9, which can soften the impulsive force acting on the glass plate 16 in the first casing 1.

What is claimed is:

1. A portable electronic apparatus comprising
a first casing constituted by bonding a front-surface cabinet and a rear-surface cabinet to each other and including a display held on a holder member made of a sheet metal and having a display surface which can be visually recognized from a front surface side,
a second casing coupled to the first casing, constituted by bonding a front-surface cabinet and a rear-surface cabinet to each other, and including a display held on a holder member made of a sheet metal and having a display surface which can be visually recognized from a front surface side,
a coupling mechanism taking at least two states of a closed state in which the display surface of the display of the first casing is covered with a rear surface of the second casing and the display surface of the display of the second casing is exposed, and an opened state in which the second casing is moved from the closed state to expose the display surfaces of both of the displays onto the same plane,
an engaging piece protruded integrally with the front-surface cabinet constituting at least one of the casings, and
the holder member which holds the display provided in the casing, is provided with an engaged piece to be engaged with the engaging piece in a protruding manner integrally, and is to be engaged with the front-surface cabinet through a mutual engagement of the engaging piece and the engaged piece.

2. The portable electronic apparatus according to claim 1, further comprising
a flat plate portion which is provided on the holder member and on which the display is to be mounted, and
a sidewall provided on the front-surface cabinet constituting one of the casings and extended along an edge of the display, wherein,
the engaged piece is protruded from an edge of the flat plate portion toward the display surface side of the display and
the engaging piece is protruded from an internal surface of the sidewall toward the engaged piece.

3. The portable electronic apparatus according to claim 1, wherein the engaging piece and the engaged piece are provided in a plurality of places along faced portions of the first casing and the second casing in the opened state.
